(19) United States
(12) Patent Application Publication
(10) Pub. No.: US 2025/0169205 A1
(43) Pub. Date: May 22, 2025

(54) METHOD OF MANUFACTURING MICRO-LENS OF IMAGE SENSOR

(71) Applicant: DB HiTek Co., Ltd., Bucheon-si (KR)

(72) Inventors: Chul Woo HWANG, Chungcheongbuk-do (KR); Ju Hwan JUNG, Chungcheongbuk-do (KR); Tae Wook KANG, Yongin-si (KR)

(21) Appl. No.: 18/402,333

(22) Filed: Jan. 2, 2024

(30) Foreign Application Priority Data
Nov. 16, 2023 (KR) 10-2023-0158880

(51) Int. Cl. H01L 27/146

(52) U.S. Cl. CPC H10F 39/024; H10F 39/8063

(57) ABSTRACT

Proposed is a method of manufacturing a micro-lens of an image sensor. More particularly, in the method of manufacturing a micro-lens of an image sensor, a micro-lens is formed to have a thicker vertical thickness than that formed by a conventional method, so that the concentrating efficiency of light incident on individual pixels is improved.

### CROSS REFERENCE TO RELATED APPLICATION

The present application claims priority to Korean Patent Application No. 10-2023-0158880, filed Nov. 16, 2023, the entire contents of which are incorporated herein for all purposes by this reference.

### BACKGROUND OF THE INVENTION

### Field of the Invention

The present disclosure relates to a method of manufacturing a micro-lens of an image sensor. More particularly, the present disclosure relates to a method of manufacturing a micro-lens of an image sensor, in which a micro-lens is formed to have a thicker vertical thickness than that formed by a conventional method, so that the concentrating efficiency of light incident on individual pixels is improved.

### Description of the Related Art

An image sensor is a device that converts an optical image originating from a subject into an electrical signal. This image sensor is a component of an image-capturing device that generates an image in mobile phone camera or the like. Image sensors can be classified into a charge coupled device (CCD) image sensor and a complementary metal oxide semiconductor (CMOS) image sensor, depending on manufacturing processes and applications. The CMOS image sensor has been widely used as a general semiconductor chip manufacturing process due to its excellent integration competitiveness, economic feasibility, and ease of connection with peripheral chips.

A micro-lens, which is a component of the CMOS image sensor, serves to increase light efficiency by concentrating light incident on individual pixels. Here, one of the factors that affects the light sensitivity of the CMOS image sensor is the thickness of the micro-lens. That is, the appropriate shape of the micro-lens varies depending on the pitch, junction depth, etc. for each individual pixel, and pixels with a large pitch usually require micro-lenses with a large vertical thickness. In particular, in the case of a backside-illuminated image sensor, the distance between a substrate and a micro-lens for each pixel is shorter than that of a frontside-illuminated image sensor, so a relatively thick micro-lens having a shape close to a hemisphere is required.

One of the methods of forming a micro-lens with a large vertical thickness is to form a thick photoresist layer for forming a micro-lens on a substrate by a coating process. When a photoresist to be used is determined, its viscosity is also determined, so there are limitations in forming micro-lenses thicker than a certain level.

FIG. 1 is a table illustrating photon detection probability (PDP) according to the thickness of a photoresist layer for forming a micro-lens.

Referring to FIG. 1, it can be seen that in the case of a single-photon avalanche diode (SPAD) pixel, when the photoresist layer for forming the micro-lens was coated on a substrate by increasing the thickness thereof by about 1 μm, the PDP in a 940 nm wavelength range was improved by about 5.57%.

FIG. 2 is a sectional view illustrating a method of manufacturing a micro-lens of an image sensor according to the related art.

Hereinafter, the method of manufacturing the micro-lens of the image sensor according to the related art will be briefly described with reference to the accompanying drawings.

Referring to FIG. 2(a), first, a first photoresist layer 910 for forming a micro-lens 950 is coated on a substrate 901 through a coating process. Here, the first photoresist layer 910 may be formed to have a predetermined thickness H0. Then, referring to FIG. 2(b), the first photoresist layer 910 except for a side where the micro-lens 950 is to be formed is removed through a patterning process. As a result, a second photoresist layer 930 is formed. The second photoresist layer 930 also has a thickness H0 that is the same or similar to that of the first photoresist layer 910. Then, referring to FIG. 2(c), the second photoresist layer 930 is reflowed by applying heat or ultraviolet (UV) light through a reflow process, and the second photoresist layer 930 is cured. As a result, the micro-lens 950 is formed.

In forming the micro-lens 950 in this way, as described above, because when a photoresist material to be used is determined, its viscosity is also determined, there are limitations in forming the micro-lens 950 to a thickness or height above a certain level.

To overcome the above problems, the inventors of the present disclosure have proposed a novel micro-lens manufacturing method, which will be described in detail later.

The foregoing is intended merely to aid in the understanding of the background of the present 5 disclosure, and is not intended to mean that the present disclosure falls within the purview of the related art that is already known to those skilled in the art.

### DOCUMENTS OF RELATED ART

(Patent document 1) Korean Patent No. 10-0705009 “Method for manufacturing micro-lens in image sensor”

### SUMMARY OF THE INVENTION

Accordingly, the present disclosure has been made keeping in mind the above problems occurring in the related art, and an objective of the present disclosure is to provide a method of manufacturing a micro-lens of an image sensor, in which a micro-lens on a substrate is formed to have a thicker vertical thickness than that formed by a conventional method, so that the concentrating efficiency of light incident on individual pixels is improved.

Another objective of the present disclosure is to provide a method of manufacturing a micro-lens of an image sensor, in which a photoresist layer is formed to have a thicker thickness than that formed by a conventional method by forming a hard mask on a substrate and then coating the photoresist layer, so that the concentrating efficiency of light incident on individual pixels is improved.

Another objective of the present disclosure is to provide a method of manufacturing a micro-lens of an image sensor, in which a relatively thick micro-lens is formed by using only a single photoresist layer rather than using different types of photoresist layers with different viscosities, so that a decrease in process efficiency is prevented.

Another objective of the present disclosure is to provide a method of manufacturing a micro-lens of an image sensor, in which a horizontal width of a micro-lens formed by a reflow process is limited by sidewalls of adjacent hard masks, so that the micro-lens is formed in a more upwardly convex shape than that formed by a conventional method.

Another objective of the present disclosure is to provide a method of manufacturing a micro-lens of an image sensor, in which a micro-lens is formed in a multi-layer structure of two or more layers formed by photoresist layers, so that the thickness of the micro-lens is controllable.

In order to achieve the above objectives, according to one aspect of the present disclosure, there is provided a method of manufacturing a micro-lens of an image sensor, the method including: forming a hard mask on a surface of a substrate; patterning the hard mask into a plurality of hard masks to remove a part of the hard mask where the micro-lens is to be formed; forming a first photoresist layer on the substrate where the part of the hard mask is removed and on the plurality of hard masks; forming a second photoresist layer by removing the first photoresist layer on the plurality of hard masks; removing the plurality of hard masks on the surface of the substrate; and forming the micro-lens by reflowing and curing the second photoresist layer.

According to another aspect of the present disclosure, a vertical thickness defined from the surface of the substrate to an upper surface of the first photoresist layer may be larger than a vertical thickness of the plurality of hard masks.

According to another aspect of the present disclosure, the second photoresist layer may be in contact with sidewalls of the plurality of hard masks.

According to another aspect of the present disclosure, an upper surface of the second photoresist layer may be located higher than upper surfaces of the plurality of hard masks.

According to another aspect of the present disclosure, there is provided a method of manufacturing a micro-lens of an image sensor, the method including: forming a hard mask on a surface of a substrate; patterning the hard mask into a plurality of hard masks to expose a part of the surface of the substrate to outside; forming a first photoresist layer on the surface of the substrate and on the plurality of hard masks; forming a second photoresist layer by removing the first photoresist layer on the plurality of hard masks; and forming the micro-lens by reflowing and curing the second photoresist layer. A separation distance between adjacent hard masks may limit a horizontal width of the micro-lens.

According to another aspect of the present disclosure, a vertical thickness defined from the surface of the substrate to an upper surface of the first photoresist layer may be larger than a vertical thickness of the plurality of hard masks.

According to another aspect of the present disclosure, the second photoresist layer may have a horizontal width smaller than the separation distance between the adjacent hard masks.

According to another aspect of the present disclosure, the second photoresist layer may not be in contact with the plurality of hard masks.

According to another aspect of the present disclosure, there is provided a method of manufacturing a micro-lens of an image sensor, the method including: forming a first photoresist layer on a surface of a substrate; forming a second photoresist layer by patterning the first photoresist layer; forming a basic structure of the micro-lens by reflowing the second photoresist layer; forming a third photoresist layer to cover the basic structure of the micro-lens on the surface of the substrate; patterning the third photoresist layer to form a fourth photoresist layer on the basic structure of the micro-lens; and forming the micro-lens by reflowing the fourth photoresist layer.

According to another aspect of the present disclosure, the third photoresist layer may have a viscosity different from a viscosity of the first photoresist layer.

According to another aspect of the present disclosure, the fourth photoresist layer may have a horizontal width smaller than a horizontal width of the basic structure of the micro-lens.

According to another aspect of the present disclosure, an upper surface of the third photoresist layer may be located higher than an upper surface of the first photoresist layer.

According to another aspect of the present disclosure, there is provided a method of manufacturing a micro-lens of an image sensor, the method including: forming a hard mask on a surface of a substrate; patterning the hard mask into a plurality of hard masks to expose a part of the surface of the substrate to outside; forming a first photoresist layer on the surface of the substrate and the plurality of hard masks; forming a second photoresist layer by removing the first photoresist layer on the plurality of hard masks; forming a basic structure of the micro-lens by reflowing the second photoresist layer; and forming an additional photoresist layer on the basic structure of the micro-lens, the surface of the substrate, and the plurality of hard masks and then patterning and reflowing the additional photoresist layer.

According to another aspect of the present disclosure, the forming, patterning, and reflowing of the additional photoresist layer may be repeated predetermined number of times.

According to another aspect of the present disclosure, a separation distance between adjacent hard masks may limit a horizontal width of the micro-lens.

According to another aspect of the present disclosure, the second photoresist layer may have a horizontal width smaller than a separation distance between adjacent hard masks.

According to another aspect of the present disclosure, a photoresist layers in contact with another photoresist layer may have a viscosity different from a viscosity of the another photoresist layer.

The present disclosure has the following effects by the above configuration.

By forming the micro-lens on the substrate to have a thicker vertical thickness than that formed by a conventional method, the concentrating efficiency of light incident on individual pixels can be improved.

In addition, by forming the photoresist layer to have a thicker thickness than that formed by a conventional method by forming the hard mask on the substrate and then coating the photoresist layer, the concentrating efficiency of light incident on individual pixels can be improved.

In addition, by forming the relatively thick micro-lens by using only the single photoresist layer rather than using different types of photoresist layers with different viscosities, a decrease in process efficiency can be prevented.

In addition, by limiting the horizontal width of the micro-lens formed by the reflow process by the sidewalls of the adjacent hard masks, the micro-lens can be formed in a more upwardly convex shape than that formed by a conventional method.

In addition, by forming the micro-lens in a multi-layer structure of two or more layers formed by photoresist layers, the thickness of the micro-lens can be controllable.

Meanwhile, the effects of the present disclosure are not limited to those mentioned above, and other effects not mentioned above can be clearly understood from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a table illustrating photon detection probability (PDP) according to the thickness of a photoresist layer for forming a micro-lens;

FIG. 2 is a sectional view illustrating a method of manufacturing a micro-lens of an image sensor according to the related art;

FIGS. 3 to 7 are sectional views illustrating a method of manufacturing a micro-lens of an image sensor according to a first embodiment of the present disclosure;

FIGS. 8 to 11 are sectional views illustrating a method of manufacturing a micro-lens of an image sensor according to a second embodiment of the present disclosure;

FIGS. 12 to 17 are sectional views illustrating a method of manufacturing a micro-lens of an image sensor according to a third embodiment of the present disclosure; and

FIGS. 18 to 23 are sectional views illustrating a method of manufacturing a micro-lens of an image sensor according to a fourth embodiment of the present disclosure.

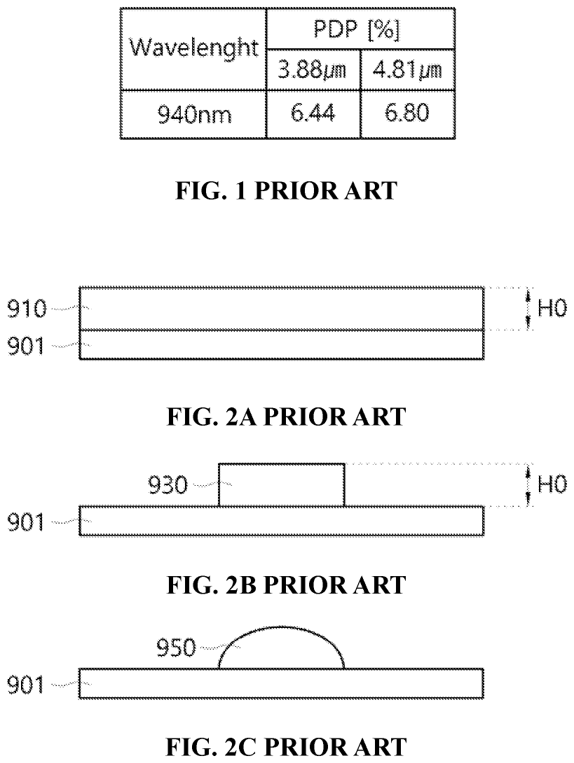

### DETAILED DESCRIPTION OF THE INVENTION

Hereinafter, exemplary embodiments of the present disclosure will be described in detail with reference to the accompanying drawings. The embodiments of the present disclosure can be modified in various forms. Therefore, the scope of the present disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the art.

When a certain embodiment may be implemented differently, a specific process order may be performed differently from the described order. For example, two consecutively described processes may be performed substantially at the same time or performed in an order opposite to the described order.

It should be noted that a method manufacturing a micro-lens of an image sensor according to the present disclosure is applicable to both a frontside-illuminated image sensor as well as a backside-illuminated image sensor.

In addition, the image sensor to which the present disclosure is applied includes a pixel area where a micro-lens is formed to allow light to be incident thereon, and the pixel area may include a plurality of unit pixel areas. For example, one micro-lens may be formed in each unit pixel area.

Hereinbelow, a method of manufacturing a micro-lens of an image sensor according to an embodiment of the present disclosure will be described in detail with reference to the accompanying drawings.

The present disclosure relates to a method of manufacturing a micro-lens of an image sensor. More particularly, the present disclosure relates to a method of manufacturing a micro-lens of an image sensor, in which a micro-lens is formed to have a thicker vertical thickness than that formed by a conventional method, so that the concentrating efficiency of light incident on individual pixels is improved.

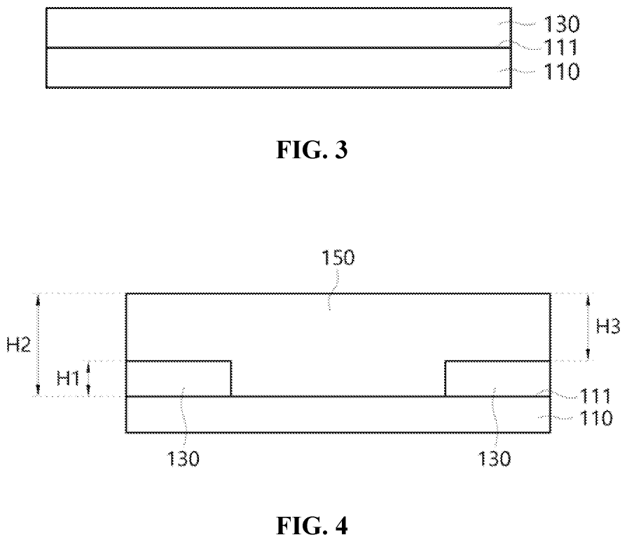

FIGS. 3 to 7 are sectional views illustrating a method of manufacturing a micro-lens 170 of an image sensor according to a first embodiment of the present disclosure.

### First Embodiment

Referring to FIG. 3, in the method of manufacturing the micro-lens 170 of the image sensor according to the first embodiment of the present disclosure, first, a hard mask 130 is formed on a surface 111 of a planarization layer or substrate 110 (hereinafter referred to as “substrate”). The hard mask 130 may include, for example, an oxide layer, or a tetraethyl orthosilicate (TEOS) layer formed by low pressure chemical vapor deposition (LPCVD), but the present disclosure is not limited thereto. In addition, the hard mask 130 may be formed on the substrate 110 to a thickness of H1 (see FIG. 4).

After that, the hard mask 130 is patterned into a plurality of hard masks 130 through a patterning process to remove a side where a second photoresist layer 151 is to be formed. Then, referring to FIG. 4, a first photoresist layer 150 for forming the micro-lens 170 is coated or formed on the substrate 110 and the hard masks 130. The first photoresist layer 150 may be formed to have a substantially flat upper surface through a spin coating process. The first photoresist layer 150 may be formed to have a thickness thicker than the thickness H1 of the hard masks 130. In detail, the first photoresist layer 150 may be formed to a thickness H2 from a surface 111 of the substrate 110, and may be formed to a thickness H3 from upper surfaces of the hard masks 130 (H2>H1, H3).

Through this process, the thickness H3 defined from the upper surfaces of the hard masks 130 to an upper surface of the first photoresist layer 150 may be substantially the same as or slightly smaller than a thickness H0 defined from a surface of a substrate 901 to an upper surface of a photoresist layer 910 according to the related art (H3=H0), but the present disclosure is not limited thereto. In addition, the thickness H2 defined from the surface 111 of the substrate 110 to the upper surface of the first photoresist layer 150 may larger than the thickness H0 defined from the surface of the substrate 901 to the upper surface of the photoresist layer 910 according to the related art (H2>H0).

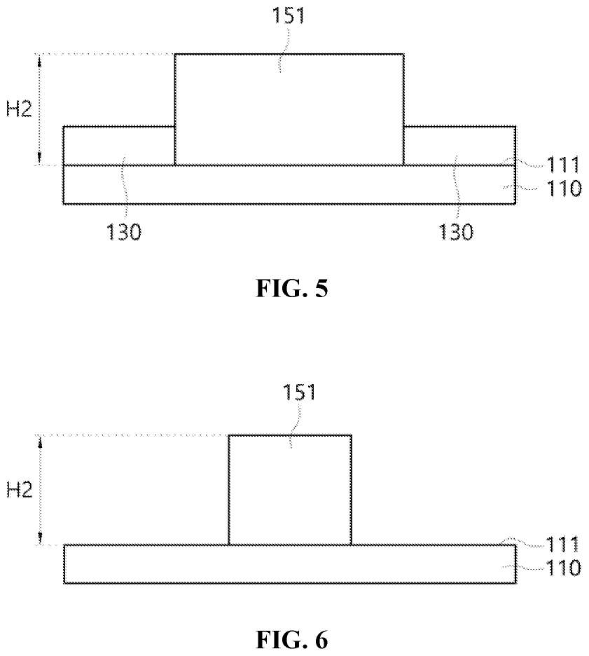

Then, referring to FIG. 5, the first photoresist layer 150 on the hard masks 130 is removed through exposure and patterning processes to form the second photoresist layer 151. As a result, as the first photoresist layer 150 on the hard masks 130 is removed, only the second photoresist layer 151 on the surface 111 of the substrate 110 between the hard masks 130 remains. Here, an upper surface of the second photoresist layer 151 may be located higher than the upper surfaces of the hard masks 130. In addition, the thickness H2 of the second photoresist layer 151 may be larger than the thickness H0 of the photoresist layer 910 according to the related art.

Then, referring to FIG. 6, the hard masks 130 on the surface 111 of the substrate 110 are removed. As a result, only the second photoresist layer 151 may remain on the surface 111 of the substrate 110. Through the above-described processes, the second photoresist layer 151 can be formed to be thicker than the photoresist layer 910 according to the related art.

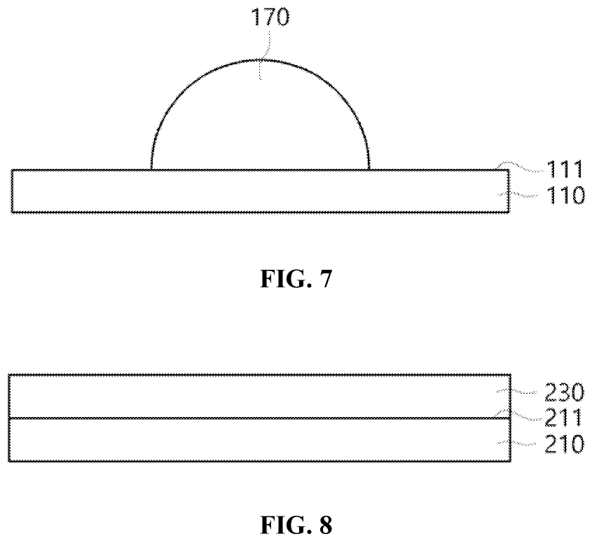

Then, referring to FIG. 7, the second photoresist layer 151 on the surface 111 of the substrate 110 is reflowed by applying heat or UV light and simultaneously the second photoresist layer 151 is cured. Through the reflow process, the micro-lens 170 cured into a desired shape is formed.

According to the first embodiment of the present disclosure, there is an advantage in that the thickness of the micro-lens 170 can be controlled by using only a single first photoresist layer 150, rather than using different types of photoresist layers with different viscosities.

FIGS. 8 to 11 are sectional views illustrating a method of manufacturing a micro-lens 270 of an image sensor according to a second embodiment of the present disclosure.

### Second Embodiment

Referring to FIG. 8, in the method of manufacturing the micro-lens 270 of the image sensor according to the second embodiment of the present disclosure, first, a hard mask 230 is formed on a surface 211 of a planarization layer or substrate 210 (hereinafter referred to as “substrate”). The hard mask 230 may include, for example, an oxide layer, or a tetraethyl orthosilicate (TEOS) layer formed by low pressure chemical vapor deposition (LPCVD), but the present disclosure is not limited thereto. In addition, as in the first embodiment, the hard mask 230 may be formed on the substrate 210 to a thickness of H.

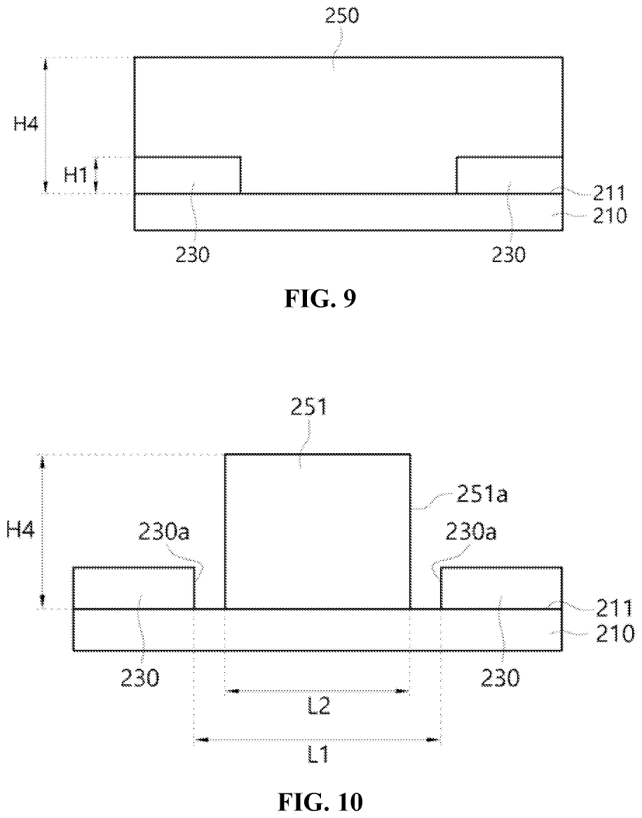

Then, referring to FIG. 9, the hard mask 230 is patterned into a plurality of hard masks 230 through a patterning process to remove a side where the micro-lens 270 is to be formed. Through this process, a separation distance L1 between adjacent hard masks 230 may be determined (see FIG. 10).

After that, a first photoresist layer 250 for forming the micro-lens 270 is formed on the surface 211 of the substrate 210 and the hard masks 230. The first photoresist layer 250 may be formed to have a substantially flat upper surface through a spin coating process. Here, the first photoresist layer 250 may be formed to have a thickness thicker than the thickness H1 of the hard masks 230. In detail, the first photoresist layer 250 may be formed to have a thickness H4 larger than the thickness H1 of the hard masks 230 (H4>H1), the thickness H4 being defined from the surface 211 of the substrate 210 to the upper surface thereof.

Then, referring to FIG. 10, the first photoresist layer 250 on the hard masks 230 is removed through exposure and patterning processes. As a result, a second photoresist layer 251 is formed. Here, opposite sidewalls 251a of the second photoresist layer 251 adjacent to the hard masks 230 may be spaced apart from sidewalls 230a of the hard masks 230. That is, a horizontal width L2 of the second photoresist layer 251 may be smaller than the separation distance L1 between the adjacent hard masks 230 (L1>L2). In addition, as described above, the second photoresist layer 251 is preferably formed so as not to be in contact with the sidewalls 230a of the hard masks 230.

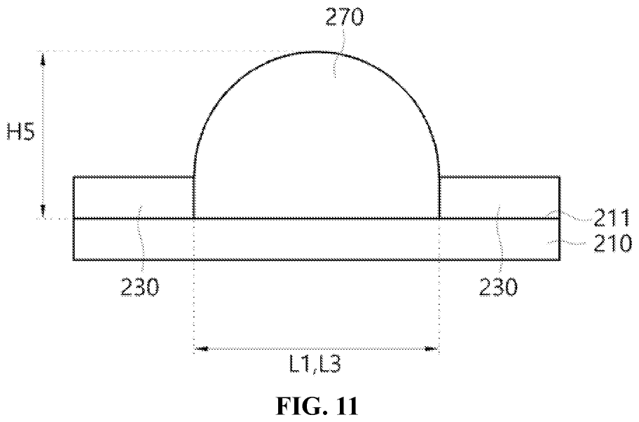

Then, referring to FIG. 11, the second photoresist layer 251 on the surface 211 of the substrate 210 is reflowed by applying heat or UV light and simultaneously the second photoresist layer 251 is cured. As a result, the micro-lens 270 is formed. During the reflow process, a horizontal width L3 of the micro-lens 270 is limited by the sidewalls 230a of the adjacent hard masks 230. That is, the horizontal width L3 of the micro-lens 270 formed through the reflow process is suppressed by the separation distance L1 between the adjacent hard masks 230. Therefore, the micro-lens 270 is formed to be more convex upward than that formed by a conventional method, so that it can have a larger vertical thickness.

According to the second embodiment of the present disclosure, there is an advantage in that the thickness of the micro-lens 270 can be controlled by using only a single first photoresist layer 250, rather than using different types of photoresist layers with different viscosities.

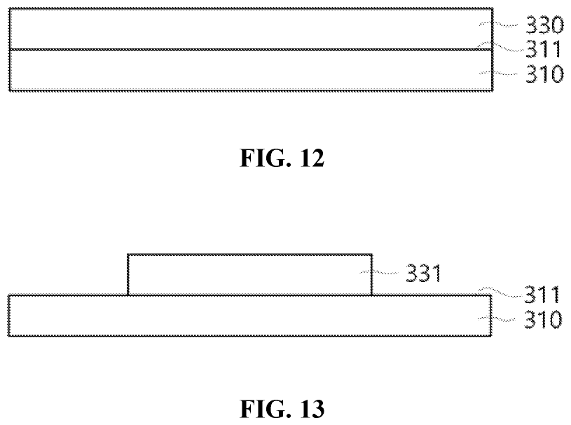

FIGS. 12 to 17 are sectional views illustrating a method of manufacturing a micro-lens 390 of an image sensor according to a third embodiment of the present disclosure.

### Third Embodiment

Referring to FIG. 12, in the method of manufacturing the micro-lens 390 of the image sensor according to the third embodiment of the present disclosure, first, a first photoresist layer 330 is formed on a surface 311 of a planarization layer or substrate 310 (hereinafter referred to as “substrate”). That is, unlike the first and second embodiments, the method of manufacturing the micro-lens 390 according to the third embodiment does not form a hard mask on the surface 311 of the substrate 310.

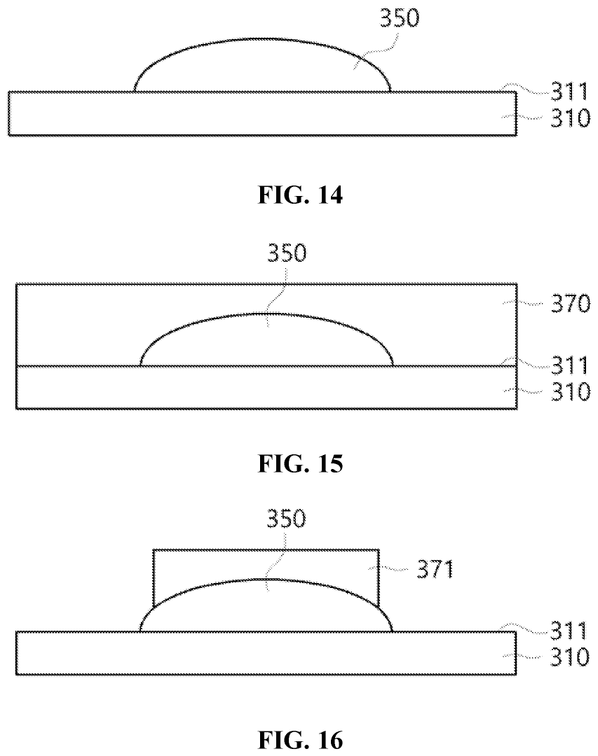

Then, referring to FIG. 13, the first photoresist layer 330 is patterned through exposure and patterning processes to form a second photoresist layer 331. Then, referring to FIG. 14, the second photoresist layer 331 is reflowed by applying heat or UV and simultaneously the second photoresist layer 331 is cured. As a result, a basic structure 350 of the micro-lens 390 (hereinafter referred to as “basic structure”) is formed. The above processes may be performed in the same manner as a conventional micro-lens manufacturing method.

Then, referring to FIG. 15, a third photoresist layer 370 is coated or formed on the surface 311 of the substrate 310 so as to cover the basic structure 350. Through this process, the third photoresist layer 370 may have a larger vertical thickness than the basic structure 350. Here, the third photoresist layer 370 may have a different viscosity than or substantially the same viscosity as the first photoresist layer 330, but the present disclosure is not limited thereto.

Then, referring to FIG. 16, the third photoresist layer 370 is patterned through exposure and patterning processes to form a fourth photoresist layer 371. Here, it is preferable that the fourth photoresist layer 371 has a smaller horizontal width than the basic structure 350, but the present disclosure is not limited thereto.

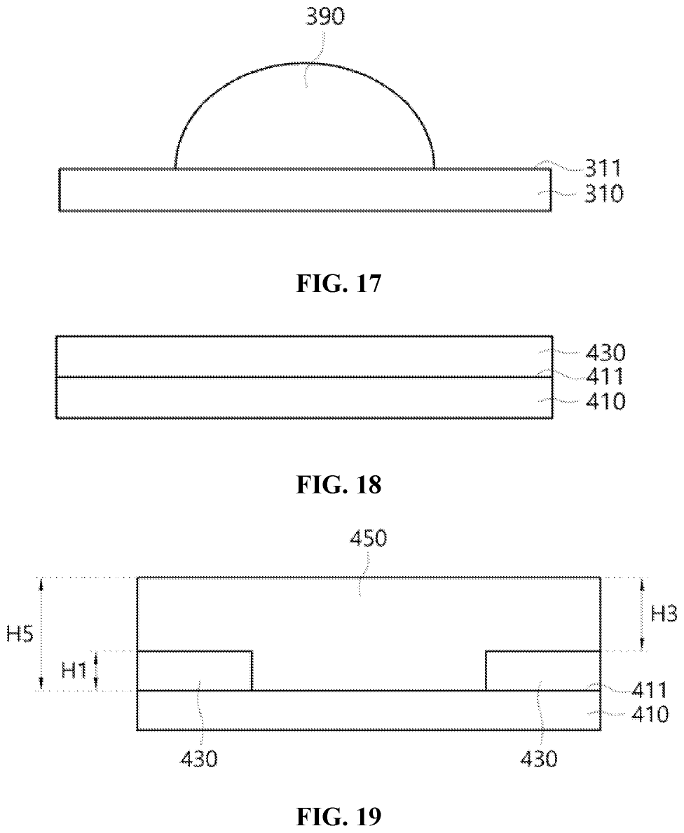

Finally, referring to FIG. 17, the fourth photoresist layer 371 is reflowed by applying heat or UV light and simultaneously the fourth photoresist layer 371 is cured. As the fourth photoresist layer 371 is cured on the basic structure 350, the micro-lens 390 having a relatively large vertical thickness may be formed. That is, the micro-lens 390 may be formed in a multi-layer structure.

In addition, in some cases, the thickness of the micro-lens 390 may be controlled as desired by forming an additional photoresist layer(s) on the cured fourth photoresist layer 370 and then performing patterning and reflow processes. That is, the micro-lens 390 may be formed in a multi-layer structure of two or more layers.

FIGS. 18 to 23 are sectional views illustrating a method of manufacturing a micro-lens 490 of an image sensor according to a fourth embodiment of the present disclosure.

### Fourth Embodiment

Referring to FIG. 18, in the method of manufacturing the micro-lens 490 of the image sensor according to the fourth embodiment of the present disclosure, first, a hard mask 430 is formed on a surface 411 of a planarization layer or substrate 410 (hereinafter referred to as “substrate”). The hard mask 430 may include, for example, an oxide layer, or a tetraethyl orthosilicate (TEOS) layer formed by low pressure chemical vapor deposition (LPCVD), but the present disclosure is not limited thereto.

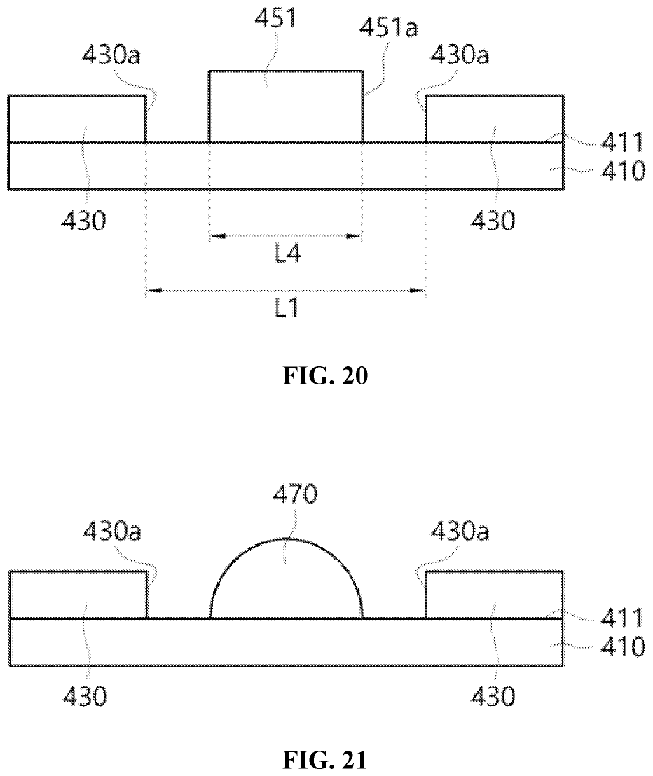

After that, the hard mask 430 is patterned into a plurality of hard masks 430 through a patterning process to remove a side where the micro-lens 490 is to be formed. Through this process, a separation distance L1 between adjacent hard masks 430 may be determined (see FIG. 20).

Then, referring to FIG. 19, a first photoresist layer 450 is coated or formed on a surface 411 of the substrate 410 and the hard masks 430. The first photoresist layer 450 may be formed to have a substantially flat upper surface through a spin coating process. In addition, a thickness H5 defined from the surface 411 of the substrate 410 to the upper surface of the first photoresist layer 450 may be larger than a thickness H1 of the hard masks 430 (H5>H1), but the present disclosure is not limited thereto.

Then, referring to FIG. 20, the first photoresist layer 450 is partially removed through exposure and patterning processes to form a second photoresist layer 451. Here, the second photoresist layer 451 may be formed between the adjacent hard masks 430. Here, a horizontal width L4 of the second photoresist layer 451 may be smaller than the separation distance L1 between the adjacent hard masks 430 (L1>L4). In addition, the second photoresist layer 451 is preferably formed so that sidewalls 451a thereof are not in contact with sidewalls 430a of the hard masks 430.

Then, referring to FIG. 21, the second photoresist layer 451 on the surface 411 of the substrate 410 is reflowed by applying heat or UV light and simultaneously the second photoresist layer 451 is cured. As a result, a basic structure 470 of the micro-lens 490 (hereinafter referred to as “basic structure”) is formed. The basic structure 470 may have a horizontal width that is not in contact with the sidewalls 430a of the adjacent hard masks 430.

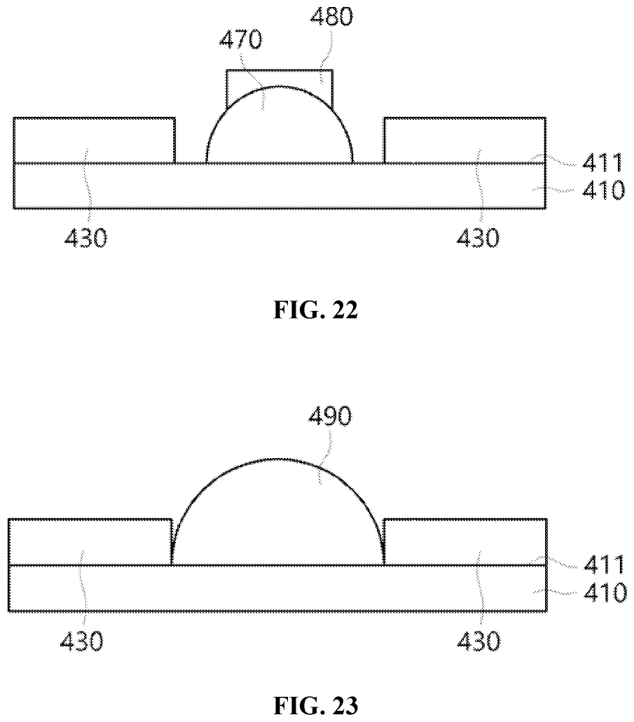

After forming the basic structure 470, referring to FIG. 22, an additional photoresist layer 480 is formed on the basic structure 470 and on the surface 411 of the substrate 410 and the hard masks 430, and the additional photoresist layer 480 is patterned through exposure and patterning processes. Then, referring to FIG. 23, the additional photoresist layer 480 is reflowed by applying heat or UV light and is simultaneously cured. Referring to FIG. 23, As a result, the micro-lens 490 is formed. That is, the micro-lens 490 may be formed in a multi-layer structure.

The cycle of formation-patterning-reflow and curing processes of the additional photoresist layer 480 may be performed N times (N=natural number). That is, after performing a cycle of coating, patterning, and reflow processes of the additional photoresist layer 480 on the basic structure 470, a cycle of coating, patterning, and reflow processes of another photoresist layer may be performed on the reflowed additional photoresist layer 480. That is, a vertical thickness of the micro-lens 490 may be controlled as desired by repeatedly performing the same process cycle. This is similar to the method of manufacturing the micro-lens 390 according to the third embodiment.

In addition, as in the second embodiment, during the reflow process, a horizontal width of the micro-lens 490 is limited by the sidewalls 430a of the adjacent hard masks 430. That is, the horizontal width of the micro-lens 490 formed through the reflow process is suppressed by the separation distance L1 between the adjacent hard masks 430. Therefore, the micro-lens 490 is formed to be more convex upward than that formed by a conventional method, so that it can have a larger vertical thickness.

In the method of manufacturing the micro-lens 490 according to the fourth embodiment, the micro-lens 490 is formed by stacking a plurality of photoresist layers. Here, it is preferable that a pair of photoresist layers in contact with each other have different viscosities, but the present disclosure is not limited thereto.

The foregoing detailed description may be merely an example of the present disclosure. Also, the inventive concept is explained by describing the preferred embodiments and will be used through various combinations, modifications, and environments. That is, the inventive concept may be amended or modified without departing from the scope of the technical idea and/or knowledge in the art. The foregoing embodiments are for illustrating the best mode for implementing the technical idea of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A method of manufacturing a micro-lens of an image sensor, the method comprising:
forming a hard mask on a surface of a substrate;
patterning the hard mask into a plurality of hard masks to remove a part of the hard mask where the micro-lens is to be formed;
forming a first photoresist layer on the substrate where the part of the hard mask is removed and on the plurality of hard masks;
forming a second photoresist layer by removing the first photoresist layer on the plurality of hard masks;
removing the plurality of hard masks on the surface of the substrate; and
forming the micro-lens by reflowing and curing the second photoresist layer.

2. The method of claim 1, wherein a vertical thickness defined from the surface of the substrate to an upper surface of the first photoresist layer is larger than a vertical thickness of the plurality of hard masks.

3. The method of claim 1, wherein the second photoresist layer is in contact with sidewalls of the plurality of hard masks.

4. The method of claim 1, wherein an upper surface of the second photoresist layer is located higher than upper surfaces of the plurality of hard masks.

5. A method of manufacturing a micro-lens of an image sensor, the method comprising:
forming a hard mask on a surface of a substrate;
patterning the hard mask into a plurality of hard masks to expose a part of the surface of the substrate to outside;
forming a first photoresist layer on the surface of the substrate and on the plurality of hard masks;
forming a second photoresist layer by removing the first photoresist layer on the plurality of hard masks; and
forming the micro-lens by reflowing and curing the second photoresist layer,
wherein a separation distance between adjacent hard masks limits a horizontal width of the micro-lens.

6. The method of claim 5, wherein a vertical thickness defined from the surface of the substrate to an upper surface of the first photoresist layer is larger than a vertical thickness of the plurality of hard masks.

7. The method of claim 5, wherein the second photoresist layer has a horizontal width smaller than the separation distance between the adjacent hard masks.

8. The method of claim 7, wherein the second photoresist layer is not in contact with the plurality of hard masks.

9. A method of manufacturing a micro-lens of an image sensor, the method comprising:
forming a first photoresist layer on a surface of a substrate;
forming a second photoresist layer by patterning the first photoresist layer;
forming a basic structure of the micro-lens by reflowing the second photoresist layer;
forming a third photoresist layer to cover the basic structure of the micro-lens on the surface of the substrate;
patterning the third photoresist layer to form a fourth photoresist layer on the basic structure of the micro-lens; and
forming the micro-lens by reflowing the fourth photoresist layer.

10. The method of claim 9, wherein the third photoresist layer has a viscosity different from a viscosity of the first photoresist layer.

11. The method of claim 9, wherein the fourth photoresist layer has a horizontal width smaller than a horizontal width of the basic structure of the micro-lens.

12. The method of claim 9, wherein an upper surface of the third photoresist layer is located higher than an upper surface of the first photoresist layer.

13. A method of manufacturing a micro-lens of an image sensor, the method comprising:
forming a hard mask on a surface of a substrate;
patterning the hard mask into a plurality of hard masks to expose a part of the surface of the substrate to outside;
forming a first photoresist layer on the surface of the substrate and the plurality of hard masks;
forming a second photoresist layer by removing the first photoresist layer on the plurality of hard masks;
forming a basic structure of the micro-lens by reflowing the second photoresist layer; and
forming an additional photoresist layer on the basic structure of the micro-lens, the surface of the substrate, and the plurality of hard masks and then patterning and reflowing the additional photoresist layer.

14. The method of claim 13, wherein the forming, patterning, and reflowing of the additional photoresist layer are repeated predetermined number of times.

15. The method of claim 13, wherein a separation distance between adjacent hard masks limits a horizontal width of the micro-lens.

16. The method of claim 13, wherein the second photoresist layer has a horizontal width smaller than a separation distance between adjacent hard masks.

17. The method of claim 14, wherein a photoresist layer in contact with another photoresist layer has a viscosity different from a viscosity of the another photoresist layer.
